(19) United States
(12) Patent Application Publication
(10) Pub. No.: US 2010/0154425 A1
(43) Pub. Date: Jun. 24, 2010

(54) STRAIN TOLERANT THERMAL BARRIER COATING SYSTEM

(75) Inventors: David A. Litton, West Hartford, CT (US); Kevin W. Schlichting, Storrs, CT (US); Michael J. Maloney, Marlborough, CT (US)

Correspondence Address: BACHMAN & LAPOINTE, P.C. (P&W), 900 CHAPEL STREET, SUITE 1201, NEW HAVEN, CT, 06510-2802, US

(73) Assignee: UNITED TECHNOLOGIES CORPORATION, Hartford, CT (US)

(21) Appl. No.: 12/343,529

(22) Filed: Dec. 24, 2008

(51) Int. Cl. F02C 7/22; C23C 16/48; F02C 7/24

(52) U.S. Cl. 60/740; 427/585; 60/722

(57) ABSTRACT

A method for forming a thermal barrier coating on a combustor panel or a fuel nozzle comprises the steps of: providing a component selected from the group consisting of a combustor panel, a bulkhead heat shield, and a fuel nozzle; optionally depositing a first layer of a metallic alloy onto the component; and depositing a ceramic composition layer using an electron beam physical vapor deposition technique. If the component is formed from a yttrium or other active element doped single crystal superalloy, the first layer may be omitted and the ceramic composition layer may be deposited directly onto a surface of the component.

### BACKGROUND

The present invention relates to a coating system for a nickel based superalloy component such as a combustor panel, a fuel nozzle, and/or a bulkhead heat shield.

Combustor panels and fuel nozzles are commonly employed in gas turbine engines. These turbine engine components in use develop hotspots. Excessive oxidation and cracking at these hotspots can lead to a shortened service life for these components.

In the past, an equiaxed nickel based superalloy has usually been used to form these components. Onto the component, an oxidation resistant metallic bondcoat (usually a NiCoCrAlY) was plasma sprayed under inert gas shrouding. The bondcoat was covered by a ceramic thermal insulating layer consisting of doped zirconia which was sprayed onto the bondcoat using air plasma spraying (APS). The coating deposited in the foregoing manner has a low thermal conductivity since the plasma spray process can be parameterized to produce porosity that is oriented predominantly perpendicular to the direction of the flow of heat through the coating. One would expect that the reduction in thermal conductivity would be the primary driver for the durability of combustor panels coated in this fashion, since the low thermal conductivity would translate to lower metal temperature, thus slower stress buildup in the coating, thus longer coating life, thus longer part life. However, it turned out that due to the nature of heat transfer in combustors, there are local hotspots on the combustor panels that run significantly hotter than the average temperature of the part. The hotspots can be so hot that they result in sintering of the prior art plasma sprayed insulating coatings. Once sintering occurs, the stress buildup in the coating is accelerated, and the life of the coating is significantly shortened. Once the coating is lost, the life of the part is significantly shortened.

In other words, the thermal capability of these prior systems however could be exceeded during use. After sufficient exposures at sufficiently high temperatures, the stresses at the interface between the thermal barrier coating (TBC) and the bondcoat become too great, thus leading to the spallation of the thermal barrier coating. Since the thermal barrier coating is thermally insulating, this leads to a significant increase in the temperature of the metallic coating and the superalloy, local to the coating spall. Also due to the large temperature gradient that results locally, thermal fatigue is enhanced at or near TBC spalls, leading to cracking of the superalloy. The result is loss of some portion of the combustor panel by oxidation as well as cracking and liberation. FIG. 1 illustrates a severely oxidized combustor panel after being removed from aeroengine service.

### SUMMARY

A thermal barrier coating system is described herein which provides better resistance to sintering than the aforementioned thermal barrier coatings.

More particularly, there is described a method for forming a thermal barrier coating which broadly comprises the steps of: providing a component selected from the group consisting of a combustor panel, a bulkhead heat shield, and a fuel nozzle; optionally depositing a first layer of a metallic alloy onto the component; and depositing a ceramic composition layer using an electron beam physical vapor deposition technique.

Still further, there is described an engine component which broadly comprises a substrate selected from the group consisting of a combustor panel, a bulkhead heat shield, and a fuel nozzle, said substrate being formed from a single crystal or DS superalloy, a metallic bondcoat layer applied to a surface of said substrate, and a ceramic composition coating applied to said metallic bondcoat layer, said ceramic composition coating having a columnar microstructure.

Yet further, there is described an engine component which broadly comprises a substrate selected from the group consisting of a combustor panel, a bulkhead heat shield, and a fuel nozzle, said substrate being formed from a yttrium-doped single crystal superalloy, and a ceramic composition layer being bonded to a surface of said substrate, said ceramic composition layer having a columnar microstructure.

Other details of the strain tolerant thermal barrier coating are set forth in the following detailed description and the accompanying drawings wherein like reference numerals depict like elements.

### BRIEF DESCRIPTION OF THE DRAWINGS

FIG. 1 illustrates a severely oxidized combustor panel after being removed from aeroengine service;

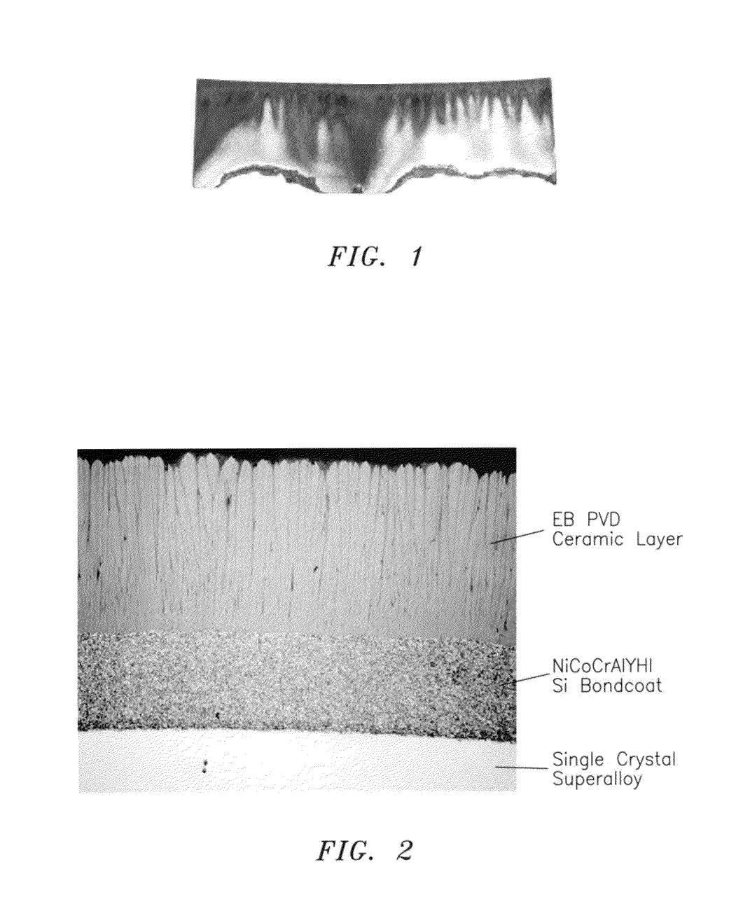

FIG. 2 is a photograph of the cross section of one exemplary coating system at a magnification of about 100×; and

FIGS. 3(a) through 3(f) illustrate elemental maps showing CMAS penetration into a PWA265 combustor coating and reduced penetration into a gadolinia stabilized zirconia EB-PVD combustor coating.

### DETAILED DESCRIPTION OF THE PREFERRED EMBODIMENT(S)

A strain tolerant thermal barrier coating system as described herein may consist of an optional first metallic bondcoat layer that is deposited onto a substrate, such as a combustor panel, a bulkhead heat shield, and/or a fuel nozzle, formed from a single crystal nickel based superalloy. The optional first layer may be formed using plasma spraying under vacuum conditions or by cathodic arc deposition also under vacuum conditions. Other processes which may be used for depositing the first bondcoat layer include electroplating, pack diffusion coating, over-the-pack diffusion coating, chemical vapor deposition, thermal evaporation, electron beam physical vapor deposition, directed vapor deposition, and combinations thereof.

The bondcoat layer may be formed from a predominantly two-phase β/γ NiCoCrAlYHfSi, single phase βNiAl or (Pt,Ni)Al, or two phase γ/γ′ NiCoCrAlYHfSi coatings (with lower Al than the β/γ systems), with and without a platinum addition.

In a predominantly two-phase β/γ NiCoCrAlYHfSi coating layer, if the volume fraction of the beta phase is X, the volume fraction of the gamma phase is predominantly 1−X. The range of X for the beta phase may be from 0.35 to 0.7 for the metallic bond coating in the as-processed state, with a particularly useful range being from 0.4 to 0.6. The volume fraction of the gamma phase may be from 0.3 to 0.65 with a useful range being from 0.4 to 0.6.

The composition of the predominantly two-phase β/γ NiCoCrAlYHfSi bond coating may consist of, in wt %, 5.0 to 40% chromium, 8.0 to 35% aluminum, 0.1 to 2.0% Group IIIB elements including, but not limited to, actinides and lanthanides, 0.1 to 2.0% hafnium, 0.1 to 7.0% silicon, and the balance selected from the group consisting of nickel, cobalt, and mixtures thereof. A particularly useful composition, in wt %, consists of from 15 to 25% chromium, 10 to 20% aluminum, up to 30% cobalt, and the balance nickel.

If the bondcoat coating layer is formed from a two phase γ/γ′ NiCoCrAlYHfSi, assuming the volume fraction of the gamma prime phase is X, the volume fraction of the gamma phase is predominantly 1−X. The range of X of the gamma prime phase may be from 0.6 to 0.95 for the metallic bond coating in the as-processed state, with a particularly useful range of X being from 0.7 to 0.9. The range of the gamma phase may be from 0.05 to 0.4 with a particularly useful range being from 0.1 to 0.3.

The composition of the two phase γ/γ′ NiCoCrAlYHfSi, in wt %, may consist of from 5.0 to 18% chromium, 7.0 to 12% aluminum, up to 15% cobalt, up to 10.0% tantalum, up to 10% molybdenum, up to 6.0% rhenium, up to 5.0% tungsten, up to 1.0% yttrium, from 0.06 to 0.5% hafnium, up to 0.3% silicon, and the balance nickel.

After a first bondcoat layer is deposited, it may be further densified by peening, and then polished using attritor milling or grit blasting.

The first bondcoat layer may be processed to maximize the density of the as-processed coating and to minimize the presence of any oxide phases within the metallic layer. The maximum density in the bondcoat may be achieved in different ways for different deposition techniques. For plasma spraying, maximum density may be achieved by spraying in a vacuum (a/k/a vacuum plasma spraying or low pressure plasma spraying); diffusing the metallic bond coat in a protective atmosphere (i.e. argon or vacuum) at 1800 to 2000 degrees Fahrenheit for 2.0 to 10 hours, and densifying the coating by peening.

For high velocity oxygen fuel (HVOF) deposition, maximum density may be achieved by spraying in air using HVOF, diffusing the metallic bond coat in a protective atmosphere (i.e. argon or vacuum) at 1800 to 2000 degrees Fahrenheit for 2.0 to 10 hours, and peening the metallic coating.

For cathodic arc deposition, maximum density may be achieved by physical vapor deposition of the metallic bond coat in a vacuum chamber, diffusing the metallic bond coat in a protective atmosphere (i.e. argon or vacuum) at 1800 to 2000 degrees Fahrenheit for 2.0 to 10 hours, and peening the metallic coating.

A second layer or thermal barrier layer may be then deposited on the bondcoat when the first layer is present. The second layer may consist of a ceramic composition with low thermal conductivity, i.e. a composition having a conductivity in the range of from 6.0 to 15 BTU in/hr ft²° F. Typical compositions of the second layer, which is a thermal barrier layer, include doped ZrO₂, CeO₂, HfO₂, or mixtures thereof. The dopants may include yttrium, indium, scandium, and the lanthanide series of metallic elements on the periodic table of elements (La through Lu)—namely, lanthanum, cerium, praseodymium, neodymium, promethium, samarium, europium, gadolinium, terbium, dysprosium, holmium, erbium, thulium, ytterbium, and lutetium. Dopant levels may range from 2.0 mol % to 50 mol %. The ceramic thermal barrier layer may be deposited using an electron beam physical vapor deposition process. Other processes which may be used to form the ceramic thermal barrier layer include directed vapor deposition, low pressure plasma spray—thin film, chemical vapor deposition, sol-gel processing, reactive sputtering, reactive cathodic arc processing, or electrophoretic deposition.

Optionally, a third or fourth layer, consisting of the ceramic described above, could be applied such that the composite properties can be achieved by layering.

If desired, one can use a ceramic interlayer. This can be done by applying a metallic bond coat of the type described hereinabove, applying a ceramic interlayer over the metallic bond coat, and then applying a low conductivity layer. The ceramic interlayer may a composition having a conductivity in the range of from 10 to 16 BTU in/hr ft²° F. Typical compositions of the second layer, which is a thermal barrier layer, include doped ZrO₂, CeO₂, HfO₂, or mixtures thereof. The dopants may include yttrium, indium, scandium, and the lanthanide series of metallic elements on the periodic table of elements (La through Lu)—namely, lanthanum, cerium, praseodymium, neodymium, promethium, samarium, europium, gadolinium, terbium, dysprosium, holmium, erbium, thulium, ytterbium, and lutetium. Dopant levels may range from 3.0 mol % to 9.0 mol %. The ceramic interlayer may be deposited using an electron beam physical vapor deposition process. Other processes which may be used to form the ceramic interlayer include directed vapor deposition, low pressure plasma spray—thin film, chemical vapor deposition, sol-gel processing, reactive sputtering, reactive cathodic arc processing, or electrophoretic deposition.

The deposition process should create the thermal barrier coating by condensation of vapor molecules, atoms or ions; reaction between vapor molecules and the solid surface of the substrate; or precipitation from solution. The deposition process usefully creates a coating with a columnar microstructure. This can be achieved in electron beam physical vapor deposition (EB-PVD), for example, by keeping the temperature of the solid surface low enough to limit surface diffusion of condensing vapor molecules. This results in columnar growth since there is insufficient diffusion to fill the gaps between growing nuclei. At the same time, the temperature of the solid surface must be kept high enough to ensure sufficient diffusion within the growing nuclei to fill voids within the columns to avoid excessive porosity, and to ensure vertical growth of the columns. If the temperature of the solid surface is too low, the columns grow with a more conical morphology that is excessively porous, leading to reduced strain tolerance, and reduced resistance to erosion and sintering. These reduced properties reduce the durability of the coating in an engine environment.

EB-PVD has been surprisingly found to be a particularly useful process for forming the second layer described herein. EB-PVD deposition allows the formation of a columnar deposit which has a higher in-plane strength and a higher in-plane tolerance which enables the deposit to withstand more load than an APS deposit. Further, EB-PVD deposited coatings better resist CMAS induced distress. The columnar deposit provides strength even though there is some CMAS penetration. The CMAS typically only partially infiltrates the deposited coating since it reacts with the columns to form a barrier layer that resists further infiltration. Thus, there is much less acceleration of damage accumulation in the EB-PVD deposited coating. In comparison, thermal spray deposits are porous and formed in planar layers with boundaries there between. The deposits lack strength in the boundaries and are brittle and prone to delamination. Due to their porosity, the CMAS often fully infiltrates the coating.

To perform EB-PVD deposition of the second layer, the parameters may be as follows: the chamber pressure may be in the range of 1e-5 Torr to 1e-3 Torr; the partial pressure of oxygen may be predominantly the same as the chamber pressure and may be accomplished by flowing oxygen during coating; the deposition rate may be in the range of 1.0 to 10.0 microinches per second with a range of from 2.5 to 3.0 microinches per second being particularly useful; and the temperature of the substrate being coated may be from 1700 to 2200 degrees Fahrenheit. The aforementioned temperature range and the partial pressure are critical to the formation of the desired columnar structure. If the temperature is too low, then the deposit lacks the claimed columnar structure and is more of a deposit that many small cauliflower shaped particles. If the temperature is too high, the deposit becomes equiaxed.

The deposition rate can be accomplished by directing an electron beam current of from 1.0 to 5.0 amps onto the source material that may be contained in a crucible, and maintaining the current in the above ranges. This causes the source material to melt, forming a pool of liquid melt. The height of the melt pool may be kept constant in the crucible, by continuously feeding material into the crucible. One means to do this is to continuously feed an ingot into the crucible (from the bottom of the crucible). For a 2.0 to 6.0 inch diameter ingot, the ingot feed rate may be from 0.5 to 2.0 inches per hour.

The deposition process may be enhanced by varying the above mentioned parameters using the design of experiments methodology, then testing the coatings that are produced by cyclic oxidation testing (such as furnace cycling or burner rig cycling) to determine the cyclic spallation life of the coatings. Maximum life in these tests correlates to optimal deposition processes.

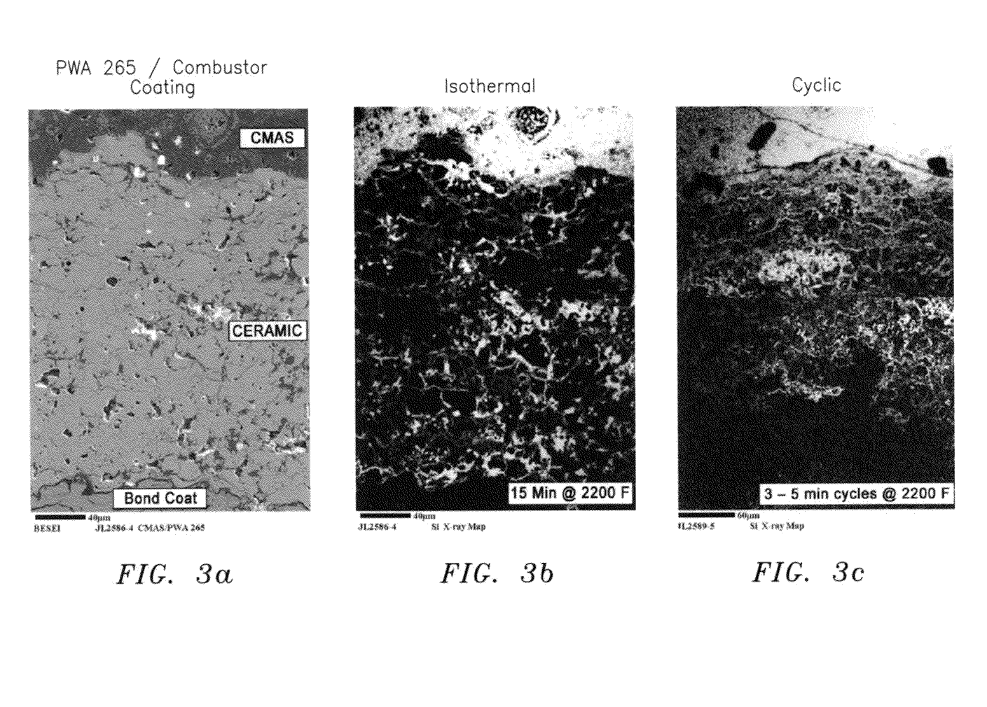

A photograph of the cross section of one exemplary system at a magnification of about 100× is shown in FIG. 2. This system consists of a single crystal superalloy onto which a NiCoCrAlYHfSi two phase β/γ metallic bondcoat was deposited by vacuum plasma spraying. The metallic bondcoat layer was heat treated to bond it to the superalloy, then peened and polished. Finally a 7 wt % yttrium doped zirconia ceramic thermal barrier layer was deposited onto the bondcoat using EB-PVD.

If reactive element doped single crystal superalloys, such as a superalloy consisting essentially of, by weight percent, 4.0-7.5% chromium, 8.0 to 12% cobalt, 0.5 to 2.5% molybdenum, 3.5 to 7.5% tungsten, 2.5 to 4.0% rhenium, 8.0 to 10% tantalum, 5.0 to 6.0% aluminum, 0.05 to 0.5% hafnium, 0.005 to 0.054% yttrium or oxygen active elements, and the balance nickel are used as the base alloy for the substrate, i.e. combustor panel, fuel nozzle, or bulkhead heat shield, the first bondcoat layer can be omitted, such that the ceramic thermal barrier can be deposited directly on a surface of the substrate formed from the superalloy.

The combination of a dense, smooth, oxide-free bondcoat (or a bare Y-enriched second generation single crystal superalloy) and the strain-tolerant columnar thermal barrier layer creates a thermal barrier coating system for substrates, such as combustor panels and fuel nozzles, that is more durable with respect to cyclic engine service. Specifically, the smooth interface between the ceramic layer and the bondcoat layer, or the advanced superalloy, minimizes the stresses that build up at the interface over the thousands of cycles of a typical run interval of an aeroengine. Furthermore, the columnar microstructure of the EB-PVD coatings are more strain-tolerant than APS coatings, thus they are more robust to the stresses that do develop at the interface. Thus, the thermal barrier coating system described herein enables a combustor to be run hotter without increasing the rate of damage accumulation of combustor panels and fuel nozzles. Running the combustor hotter results in higher engine performance or efficiency.

Although thermal barrier coatings have been applied to turbine hardware, it is surprising that significant benefits can be obtained by applying a thermal barrier coating such as that described herein to combustor panels and fuel nozzles. The reasons for these surprising benefits are as follows.

Since coatings produced by vapor deposition have better sintering resistance, the presence of hotspots does not accelerate stress buildup and coating loss nearly as much. This is despite the fact that the metal temperature beneath the second (insulating ceramic) layer is higher for the vapor deposited coatings. The result is a surprisingly longer part life for parts coated with vapor deposited coatings than for parts with plasma sprayed coatings.

A second advantage is as follows. Vapor deposited coatings are more CMAS resistant. CMAS stands for calcium magnesium aluminum and silicon and is a catch-all term for the chemistry of deposits that form on top of the topcoat of thermal barrier coating systems during engine operation. If deposits form on the coating due to ingested dirt impacting the combustor panels and sticking to the coating surface, the deposits will melt if the temperature of the coating surface is high enough (typically greater than 2200 degrees Fahrenheit).

Thermally sprayed coatings form by deposition of liquid droplets impinged on the component or part. The droplets freeze on hitting the part, forming what is termed as “splats”, which are very roughly disc shaped. Thus, the microstructure of the coating consists of randomly stacked splats, which are comparable to randomly stacked pancakes. If this molten CMAS forms on plasma sprayed coatings, it wets the boundaries between the splats, and tends to attack and dissolve the bonds between the splats. Thus, CMAS-attacked thermally sprayed coatings tend to flake off from the surface downward, relatively quickly, until the coating is gone. This dramatically reduces part life. Since combustor panels have hotspots, this distress tends to happen in the hotspots, leading to exposed bare spots on the parts. This also leads to large thermal gradients in the parts, (since areas of the part that were exposed by loss of coating are running much hotter than the rest of the part). These thermal gradients lead to thermomechanical fatigue cracking, which further shortens the life of the parts.

The microstructures of vapor deposited coatings can be parameterized to be columnar, primarily by controlling the temperature of the part being coated to between 0.39 T_{m, coating} and 0.43 T_{m, coating} where T_{m, coating} refers to the melting point of the material being coated. This columnar microstructure results in a coating that has significant strength along the long axes of the columns, but, due to the gaps between columns, has great compliance or strain-tolerance in the plane of the coating. Since the coatings are strong along the length of the columns, molten CMAS does not result in rapid flaking off of the coating from the top down. This makes the columnar microstructure of vapor deposited coatings more durable than the stacked splat microstructure of thermally sprayed coatings, with respect to CMAS.

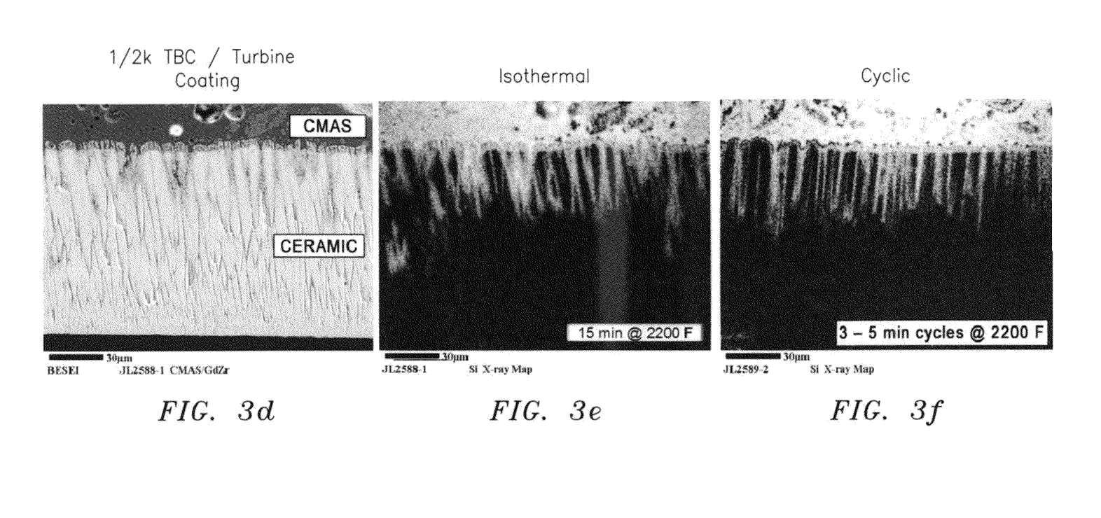

This benefit was demonstrated in the laboratory by performing molten dirt/sand testing. Dirt and/or sand ingested into the gas turbine engine is typically made up of a mixture of calcium, magnesium, aluminum, and silicon oxides or sulfates and is typically termed CMAS. When this mixture is heated, it forms a low melting eutectic compound which infiltrates and attacks the thermal barrier coating. A low conductivity doped stabilized zirconia EB-PVD coating has shown a greater resistance to penetration of this CMAS than the current APS combustor coating. Furnace test results are shown in FIGS. 3(a)-3(f). FIGS. 3(a) and 3(d) show the optical photo of the coatings in cross section. The first coating shown in FIG. 3(a) is a typical air plasma sprayed combustor coating. The second coating shown in FIG. 3(d) is a coating formed as described herein with a low conductivity doped stabilized zirconia EB-PVD coating layer applied to a combustor panel. FIGS. 3(b), (c), (e), and (f) are chemical maps of silicon for an isothermal exposure at 2200 degrees Fahrenheit for 15 minutes and a cyclic exposure of three five minute cycles at 2200 degrees Fahrenheit respectively. As can be seen from the photos, silicon penetrates 80 to 100% of the combustor coating shown in FIG. 3(a), while the low conductivity doped coating in FIG. 3(d) shows approximately 33% penetration.

The coatings described herein are different in that they are the first application of a low conductivity doped stabilized zirconia EB-PVD coating to a combustor panel, the first application of a CMAS resistant thermal barrier coating to a combustor panel, and the first application of an EB-PVD type coating to a combustor panel.

In accordance with the present disclosure, there has been provided a strain tolerant thermal barrier coating for combustor panels and fuel nozzles. While the coating and the method for forming same have been described in the context of specific embodiments thereof, other unforeseeable alternatives, modifications, and variations may become apparent to those skilled in the art having read the foregoing description. Accordingly, it is intended to embrace those alternatives, modifications, and variations which fall within the broad scope of the appended claims.

What is claimed is:

1. A method for forming a thermal barrier coating comprising the steps of:
providing a component selected from the group consisting of a combustor panel, a bulkhead heat shield, and a fuel nozzle;
optionally depositing a first layer of a metallic alloy onto said component; and
depositing a ceramic composition layer using an electron beam physical vapor deposition technique.

2. The method according to claim 1, wherein said first layer depositing step comprises depositing a predominantly two phase β/γ NiCoCrAlYHfSi coating.

3. The method according to claim 1, wherein said first layer depositing step comprises depositing a predominantly two phase β/γ NiCoCrAlYHfSi coating having a composition in weight percent consisting of from 5.0 to 40% chromium, 8.0 to 35% aluminum, 0.1 to 2.0% Group IIIB elements including, but not limited to, actinides and lathanides, 0.1 to 2.0% hafnium, 0.1 to 7.0% silicon, and the balance selected from the group consisting of nickel, cobalt and mixtures thereof.

4. The method according to claim 3, wherein said first layer depositing step further comprises depositing a two phase β/γ NiCoCrAlYHfSi coating wherein the beta phase is present in a volume fraction in the range of from 0.35 to 0.7 and the gamma phase is present in a volume fraction in the range of from 0.3 to 0.65.

5. The method according to claim 3, wherein said first layer depositing step further comprises depositing a two phase β/γ NiCoCrAlYHfSi coating wherein the beta phase is present in a volume fraction in the range of from 0.4 to 0.6 and the gamma phase is present in a volume fraction in the range of from 0.4 to 0.6.

6. The method according to claim 1, wherein said first layer depositing step comprises depositing a predominantly two phase β/γ NiCoCrAlYHfSi coating having a composition in weight percent consisting of from 15 to 25% chromium, 10 to 20% aluminum, up to 30 wt % cobalt, and the balance nickel.

7. The method according to claim 1, wherein said first layer depositing step comprises depositing a gamma-gamma prime bond coating having a composition in wt % consisting of from 5 to 18% chromium, 7.0 to 12% aluminum, up to 15% cobalt, up to 10.0% tantalum, up to 10% molybdenum, up to 6.0% rhenium, up to 5.0% tungsten, up to 1.0% yttrium, from 0.06 to 0.5% hafnium, up to 0.3% silicon, and the balance nickel.

8. The method according to claim 7, wherein said first layer depositing step further comprises depositing said gamma-gamma prime bond coating with the gamma prime phase being present in a volume fraction of from 0.6 to 0.95 and the gamma phase is present in a fraction of from 0.05 to 0.4.

9. The method according to claim 7, wherein said first layer depositing step further comprises depositing said gamma-gamma prime bond coating with the gamma prime phase being present in a volume fraction of from 0.7 to 0.9 and the gamma phase is present in a fraction of from 0.1 to 0.3.

10. The method according to claim 1, wherein said first layer depositing step further comprises depositing a single phase β NiAl coating.

11. The method according to claim 1, wherein said first layer depositing step further comprises depositing a coating selected from the group consisting of platinum-aluminide coatings and nickel-platinum-aluminide coatings.

12. The method according to claim 1, further comprising depositing said first layer, densifying the first layer by peening, and polishing the densified first layer.

13. The method according to claim 12, wherein said densifying step comprises diffusing the first layer in a protective atmosphere selected from the group consisting of argon and a vacuum at a temperature in the range of from 1800 to 2000 degrees Fahrenheit for 2.0 to 10 hours, and densifying the coating by peening.

14. The method according to claim 1, wherein said component providing step comprises providing a combustor panel formed from a single crystal nickel based superalloy.

15. The method according to claim 1, wherein said component providing step comprises providing a combustor panel formed from a yttrium doped single crystal superalloy and depositing said ceramic composition layer directly onto said yttrium doped single crystal superalloy.

16. The method according to claim 1, wherein said ceramic composition layer depositing step comprises depositing an oxide selected from the group consisting of zirconia, ceria, hafnia, and mixtures thereof doped with from 2 mol % to 50 mol % of a dopant selected from the group consisting of yttrium, indium, scandium, lanthanum, cerium, praseodymium, neodymium, promethium, samarium, europium, gadolinium, terbium, dysprosium, holmium, erbium, thullium, ytterbium, and lutetium.

17. The method according to claim 1, wherein said ceramic composition layer depositing step comprises depositing said ceramic composition layer using a process which creates the layer by at least one of condensation of vapor molecules, atoms or ions, reaction between vapor molecules and the solid surface, and precipitation from a solution.

18. The method according to claim 1, wherein said ceramic composition layer depositing step comprises creating a coating layer with a columnar microstructure.

19. The method according to claim 1, wherein said ceramic composition depositing step comprises maintaining said component in a chamber at a pressure in the range of 1e-5 to 1e-3 Torr, applying a partial oxygen pressure in the range of 1e-5 to 1e-3 Torr, maintaining an electron beam current in the range of 1.0 to 5.0 amps onto a source material contained in a crucible, maintaining component temperature within the range of from 1800 degrees Fahrenheit to 2100 degrees Fahrenheit, feeding an ingot of said source material into said crucible at a rate of 0.5 to 2.0 inches per hour, and maintaining a deposition rate of 1.0 to 5.0 microinches per second.

20. An engine component comprising a substrate selected from the group consisting of a combustor panel, a bulkhead heat shield, and a fuel nozzle, said substrate being formed from a single crystal superalloy, a metallic bondcoat layer applied to a surface of said substrate, and a ceramic composition coating applied to said metallic bondcoat layer, said ceramic composition coating having a columnar microstructure.

21. The engine component of claim 20, wherein said substrate is a combustor panel.

22. The engine component of claim 20, wherein said substrate is a fuel nozzle.

23. The engine component of claim 20, wherein said substrate is a bulkhead heat shield.

24. The engine component of claim 20, wherein said bondcoat layer is formed from a predominantly two phase β/γ NiCoCrAlYHfSi coating having a composition in weight percent consisting of from 5.0 to 40% chromium, 8.0 to 35% aluminum, 0.1 to 2.0% Group IIIB elements including but not limited to actinides and lanthanides, 0.1 to 2.0% hafnium, 0.1 to 7.0% silicon, and the balance selected from the group consisting of nickel, cobalt, and mixtures thereof.

25. The engine component of claim 24, wherein method according to claim 3, wherein the beta phase is present in a volume fraction in the range of from 0.35 to 0.7 and the gamma phase is present in a volume fraction in the range of from 0.3 to 0.65.

26. The engine component of claim 24, wherein the beta phase is present in a volume fraction in the range of from 0.4 to 0.6 and the gamma phase is present in a volume fraction in the range of from 0.4 to 0.6.

27. The engine component according to claim 20, wherein said bondcoat layer is formed from a predominantly two phase β/γ NiCoCrAlYHfSi coating having a composition in weight percent consisting of from 15 to 25% chromium, 10 to 20% aluminum, up to 30% cobalt, and the balance nickel.

28. The engine component according to claim 20, wherein said bondcoat layer is formed from a gamma-gamma prime bond coating having a composition in wt % consisting of from 5.0 to 18% chromium, 7.5 to 12% aluminum, up to 15% cobalt, up to 10.0% tantalum, up to 10% molybdenum, up to 6.0% rhenium, up to 5.0% tungsten, up to 1.0% yttrium, from 0.06 to 0.5% hafnium, up to 0.3% silicon, and the balance nickel.

29. The engine component according to claim 28, wherein said gamma-gamma prime bond coating has a gamma prime phase present in a volume fraction of from 0.6 to 0.95 and a gamma phase present in a fraction of from 0.05 to 0.4.

30. The engine component according to claim 28, wherein said gamma-gamma prime bond coating has a gamma prime phase present in a volume fraction of from 0.7 to 0.9 and a gamma phase present in a fraction of from 0.1 to 0.3.

31. The engine component according to claim 20, wherein said bondcoat layer comprises a single phase β NiAl coating.

32. The engine component according to claim 20, wherein said bondcoat layer comprises a coating selected from the group consisting of platinum-aluminide coatings and nickel-platinum-aluminide coatings.

33. The engine component according to claim 20, wherein said ceramic composition layer comprises an oxide selected from the group consisting of zirconia, ceria, hafnia, and mixtures thereof doped with from 2 mol % to 50 mol % of a dopant selected from the group consisting of yttrium, indium, scandium, lanthanum, cerium, praseodymium, neodymium, promethium, samarium, europium, gadolinium, terbium, dysprosium, holmium, erbium, thulium, ytterbium, and lutetium.

34. An engine component comprising a substrate selected from the group consisting of a combustor panel, a bulkhead heat shield, and a fuel nozzle, said substrate being formed from a yttrium-doped single crystal superalloy and a ceramic composition layer being bonded to a surface of said substrate, said ceramic composition layer having a columnar microstructure.

35. The engine component according to claim 34, wherein said ceramic composition layer comprises an oxide selected from the group consisting of zirconia, ceria, hafnia, and mixtures thereof doped with from 2 mol % to 50 mol % of a dopant selected from the group consisting of yttrium, indium, scandium, lanthanum, cerium, praseodymium, neodymium, promethium, samarium, europium, gadolinium, terbium, dysprosium, holmium, erbium, thulium, ytterbium, and lutetium.

36. The engine component according to claim 34, wherein said substrate is a combustor panel.

37. The engine component according to claim 34, wherein said substrate is a fuel nozzle.
